(19) United States
(12) Patent Application Publication
(10) Pub. No.: US 2025/0386445 A1
(43) Pub. Date: Dec. 18, 2025

(54) ENCLOSURE INCLUDING MULTI-MODAL HINGE SYSTEM AND RELATED METHODS

(71) Applicant: Advanced Charging Technologies, Inc., Fountain Valley, CA (US)

(72) Inventor: JON K. HOLMAN, LAKE MARY, FL (US)

(21) Appl. No.: 18/741,117

(22) Filed: Jun. 12, 2024

(51) Int. Cl. H05K 5/02

(52) U.S. Cl. CPC H05K 5/0226

(57) ABSTRACT

An enclosure may include a chassis having an opening therein, and a plurality of hinge pins coupled to the chassis adjacent the opening, with at least one first hinge pin positioned adjacent a first side of the opening and at least one second hinge pin positioned adjacent a second side of the opening opposite the first side. The enclosure may further include a cover for the opening, and a plurality of bolts rotatably carried by the cover. Each bolt may be aligned with a respective hinge pin when the cover is positioned over the opening in the chassis, and each bolt being rotatable between locked and unlocked positions with respect to its corresponding hinge pin such that the cover may be selectively rotatable about the first hinge pin(s), the second hinge pin(s), or removed from the chassis.

### TECHNICAL FIELD

The present disclosure generally relates to enclosures, and more particularly to hinge assemblies for enclosures such as equipment chassis and related methods.

### BACKGROUND

Enclosures are used in a number of applications for housing equipment, such as racking systems for electrical/electronic and computer components. Such enclosures typically include a chassis with a rack mount assembly to which the components are attached, and a door or cover that is connected to the chassis with hinges.

While such enclosures provide a generally convenient and efficient way for storing a small or large number of components, access to the components may sometimes be a challenge depending on the installation location and the way in which the door is configured. Various approaches have been attempted to improve access to equipment in such enclosures. One example is set forth in U.S. Pat. Pub. No. 2007/0007411, which discloses a hinged swing bracket assembly for a telecommunications rack system that has first, second and third arms. The first arm has a first end and a second end and is adapted to be connected to a support. The second arm has first and second ends. The first end of the second arm is pivotally connected to the first arm and the second end of the second arm is releasably connected to the first end of the first arm. The third arm has first and second ends. The first end of the third arm is pivotally connected to the second end of the second arm, and the second end of the third arm is releasably connected to the first end of the second arm.

Despite the existence of such systems, further enhancements to enclosures for providing improved access capabilities to components therein may be desirable in certain applications.

### SUMMARY

An enclosure may include a chassis having an opening therein, and a plurality of hinge pins coupled to the chassis adjacent the opening, with at least one first hinge pin positioned adjacent a first side of the opening and at least one second hinge pin positioned adjacent a second side of the opening opposite the first side. The enclosure may further include a cover for the opening, and a plurality of bolts rotatably carried by the cover. Each bolt may be aligned with a respective hinge pin when the cover is positioned over the opening in the chassis, and each bolt being rotatable between locked and unlocked positions with respect to its corresponding hinge pin such that: when the bolt corresponding to the at least one first hinge pin is in the locked position and the bolt corresponding to the at least one second hinge pin is in the unlocked position, the cover is rotatable about the at least one first hinge pin; when the bolt corresponding to the at least one second hinge pin is in the locked position and the bolt corresponding to the at least one first hinge pin is in the unlocked position, the cover is rotatable about the at least one second hinge pin; and when the bolts corresponding to the at least one first hinge pin and the at least one second hinge pin are in the unlocked position, the cover is removable from the chassis.

In an example implementation, each bolt may have a slot therein configured to engage the corresponding hinge pin when the bolt is rotated to the locked position, and to release the corresponding hinge pin when the bolt is rotated to the unlocked position. In some embodiments, the enclosure may further include a plurality of bolt capture blocks removably attached to the cover and each for receiving a respective bolt therein. More particularly, each bolt may have a locking pin hole, and each bolt capture block may have a locking pin groove therein for inserting a locking pin into the locking pin hole of the corresponding bolt. In accordance with one example, the locking pin groove may be configured to allow rotation of the locking pin between first and second stop positions.

In some embodiments, each hinge pin may have a rounded tip. Furthermore, in an example implementation the at least one first hinge pin may comprise at least two first hinge pins, and the at least one second hinge pin may comprise at least two second hinge pins. In an example embodiment the enclosure may further include a plurality of hinge pin bases each coupling a respective hinge pin to the chassis. The enclosure may also include at least one rack mount fixture carried within the chassis and configured to receive at least one electronic component.

A related hinge system for, and method for making, an enclosure such as the one described briefly above are also provided. The method may include coupling a plurality of hinge pins to a chassis adjacent an opening thereof, with at least one first hinge pin positioned adjacent a first side of the opening and at least one second hinge pin positioned adjacent a second side of the opening opposite the first side. The method may further include attaching a plurality of bolts to a cover for the opening of the chassis, with each bolt being aligned with a respective hinge pin when the cover is positioned over the opening in the chassis, and each bolt being rotatable between locked and unlocked positions with respect to its corresponding hinge pin such that: when the bolt corresponding to the at least one first hinge pin is in the locked position and the bolt corresponding to the at least one second hinge pin is in the unlocked position, the cover is rotatable about the at least one first hinge pin; when the bolt corresponding to the at least one second hinge pin is in the locked position and the bolt corresponding to the at least one first hinge pin is in the unlocked position, the cover is rotatable about the at least one second hinge pin; and when the bolts corresponding to the at least one first hinge pin and the at least one second hinge pin are in the unlocked position, the cover is removable from chassis.

### BRIEF DESCRIPTION OF THE DRAWINGS

FIG. 1 is a perspective view of an enclosure including a hinge assembly providing bi-directional cover operation and removability in accordance with an example embodiment.

FIG. 2 is a perspective view of an example hinge pin block for a hinge assembly of the enclosure of FIG. 1.

FIG. 3 is a perspective view of an example bolt capture block for the hinge assembly of the enclosure of FIG. 1.

FIG. 4 is a perspective view of an example quick release bolt for the hinge assembly of the enclosure of FIG. 1.

FIGS. 5A and 5B are side views showing the relationship between the quick release bolt of FIG. 4 and hinge pin block of FIG. 2 in locked and unlocked positions of the quick release bolt, respectively.

FIGS. 6 and 7 are a series of perspective views illustrating installation of the quick release bolt of FIG. 4 in the bolt capture block of FIG. 3.

FIGS. 8-12 are a series of perspective and side views showing assembly of the enclosure of FIG. 1 with installation of the hinge system and cover in an example implementation.

### DETAILED DESCRIPTION

The present description is made with reference to various example embodiments. However, many different embodiments may be used, and thus, the description should not be construed as limited to the embodiments set forth herein. Rather, these embodiments are provided so that this disclosure will be thorough and complete. Like numbers refer to like elements throughout.

As discussed above, on typical enclosures for equipment such as computer servers, battery chargers, telecommunications equipment, sound equipment, etc., the hinged doors or covers are handed, i.e., they have a hinged side and open from the opposite side. This can be inconvenient if the installation or placement of the enclosure requires the opening side to be against an obstruction, for example. The present disclosure provides a hinge system incorporating double-acting (or bi-directional) hinges which can open either left or right-handed, or allow for complete locking in place or removal of the cover.

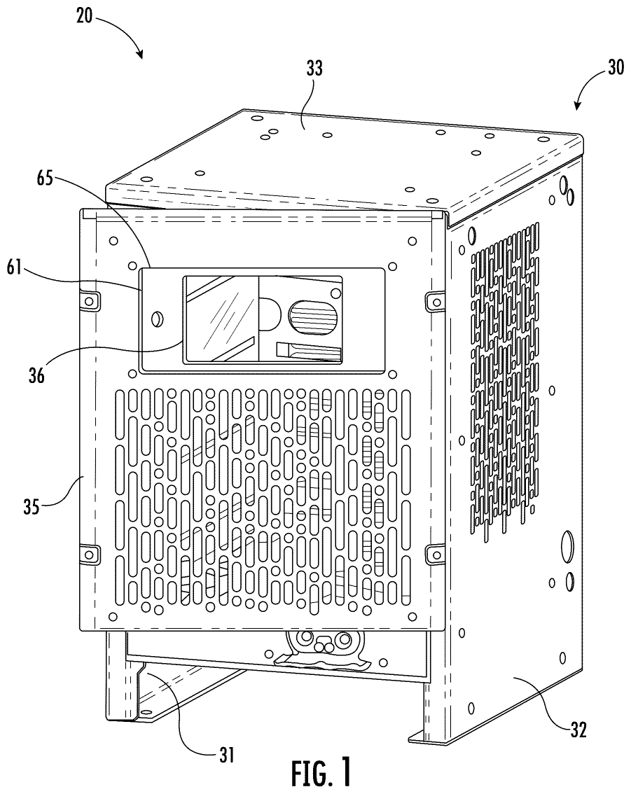

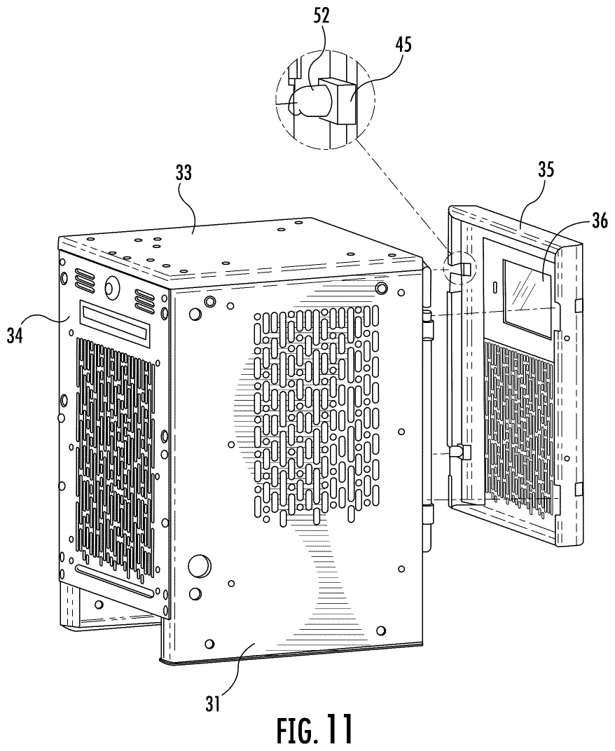

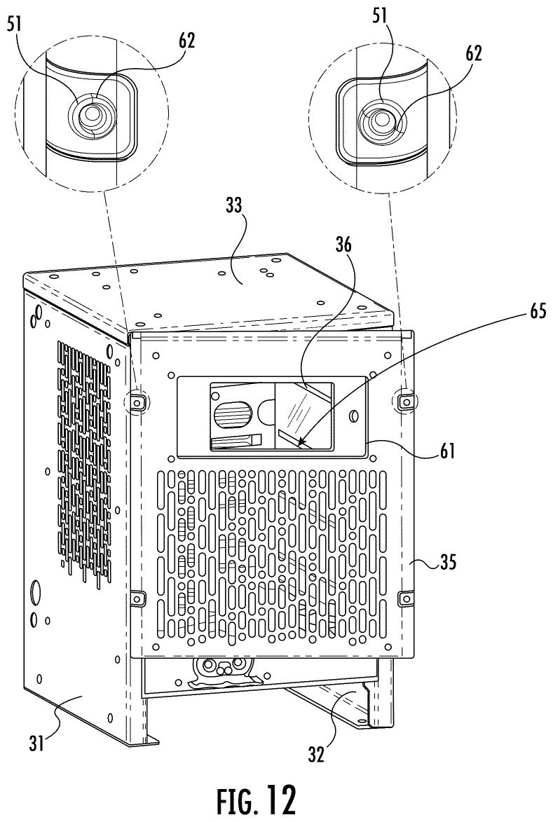

Referring initially to FIG. 1, an enclosure 20 which may be used for industrial equipment applications such as those noted above is first described. The enclosure 30 illustratively includes a chassis 30 having a left panel 31, right panel 32, top panel 33, back panel 34 (see FIG. 11) and bottom panel (not shown). The panels 31-34 may be made out of metal (e.g., steel), and include perforations or vent holes to allow thermal venting for heat generating electrical or electronic components (chargers, power supplies, etc.) mounted within the chassis 30. In some embodiments a panel such as the top panel 33, back panel 34 and/or bottom panel may be omitted. Moreover, the illustrated chassis 30 is configured for mounting on a floor or elevated platform, but in other embodiments the chassis may be configured for wall mounting, or provide the option for either type of mounting. In this regard, it should be noted that the enclosure 20 need not always be used for industrial equipment, and that the enclosure could be made out of different materials (e.g., wood, etc.) and used for other applications, such as cabinets or storage lockers, for example.

The front of the chassis 30 has an opening therein for installing/accessing the equipment to be installed therein via a cover 35 installed over the opening. For purposes of this description, the term “cover” as used herein is intended to include various types of hatches, panels or doors that are suitable for closing off the opening in the chassis 30, as will be understood by those skilled in the art. The cover 35 also includes an optional windowpane 36 in the illustrated example.

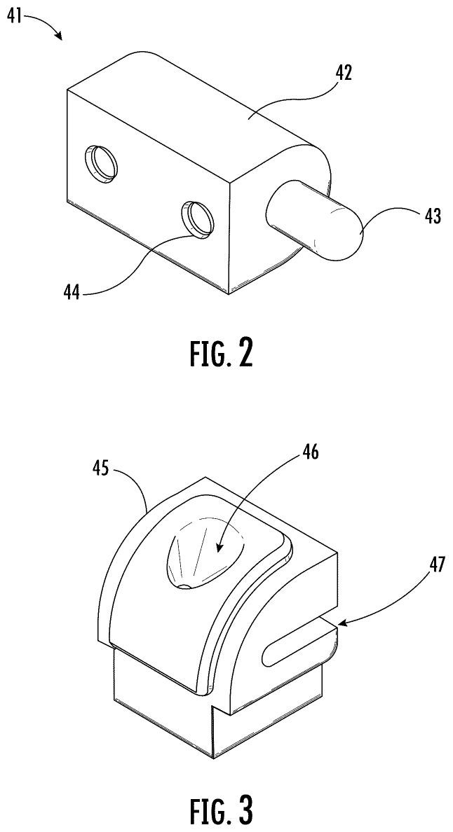

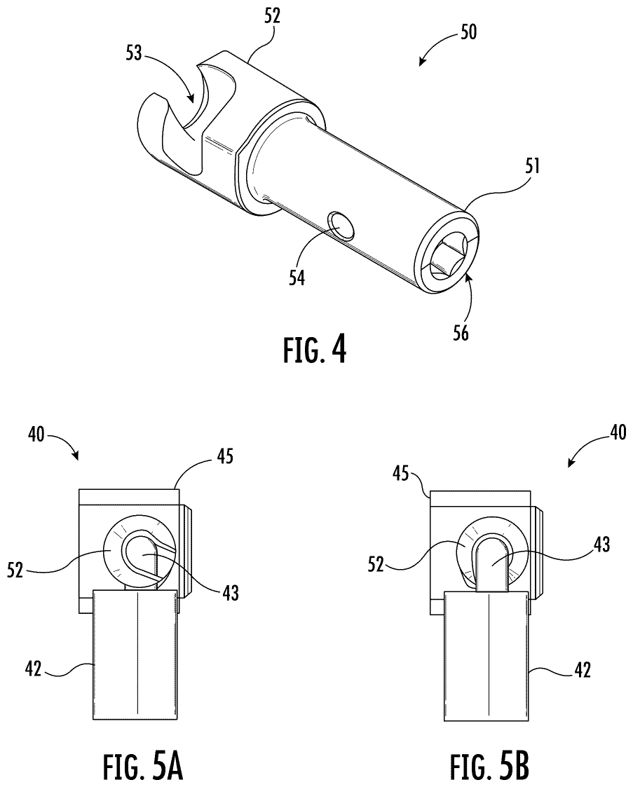

Referring additionally to FIGS. 2-5B, components of an example hinge assembly 40 for the enclosure 20 are now described. Each hinge assembly 40 illustratively includes a hinge pin block 41 (FIG. 2) having a base 42 and a hinge pin 43 carried by the base. The base 42 includes a plurality of threaded holes 44 by which the base is secured to the front of the chassis 30 with screws, as will be discussed further below. However, it should be noted that in other embodiments, the base 42 may be otherwise connected to the chassis 30 (e.g., by welding, etc.), or in some embodiments may be integrally formed as part of the chassis. The hinge pin 43 has a rounded tip in the illustrated example to facilitate locking and unlocking, as will be discussed further below.

The hinge assembly 40 further illustratively includes a bolt capture block 45 (FIG. 3) which defines a bolt receiving channel 46 therethrough, as well as a locking pin groove 47, which will be discussed further below. However, the function of the example bolt capture block 45 may be achieved with different configurations in other embodiments. For example, in some covers 35 the bolt receiving channel 46 may be integrally formed as part of the cover itself.

The next component of the hinge assembly 40 is a quick release bolt 50 having a proximal end 51 and a distal end 52. The proximal end 51 has a hex socket receptacle 56 therein, although other suitable receptacles (screwdriver, star bit, etc.) may also be used in different embodiments. A slot 53 is defined in the distal end 52, which is sized to fit over the rounded tip of the hinge pin 43, as will be discussed further below. The quick release bolt 50 is sized to fit within the bolt receiving channel 46 and rotate between a locked position (FIG. 5A) where the slot 53 engages the hinge pin 43 within the distal end 52, and an unlocked position (FIG. 5B) where the slot releases the hinge pin from the distal end. The quick release bolt 50 also has a locking pin hole 54 therein, which will be discussed further below.

In the illustrated example, there are two hinge assemblies 40 for each side of the cover 35. Because the quick release bolt 50 in each hinge assembly 40 can be rotated between locked and unlocked position when the cover 35 is positioned on the hinge pins 43, the hinges may be selectively locked or unlocked to allow bi-directional opening or swinging of the cover 35 on the hinge pins. More particularly, when the quick release bolts 50 on the right side of the cover 35 are in the locked position and the bolts on the left side of the cover are in the unlocked position, the cover is rotatable about the right-side hinge pins 43 (as shown in FIG. 1). When the bolts 50 on the left side of the cover 35 are in the locked position and the bolts on the right side of the cover are in the unlocked position, the cover is rotatable about the left side hinge pins 43 (FIG. 12). When all of the bolts 50 of the left and right-side hinge assemblies 40 are in the unlocked position, the cover 35 may be removed from (or positioned on) the hinge pins 43. Conversely, when all of the left and right-side hinge assemblies 40 are in the locked position, the cover 35 is fix mounted to the chassis 30 over the opening, and cannot swing open to the left or right.

It should be noted that in some embodiments, a single hinge assembly 40, or more than two hinge assemblies, may be used for the left or the right side of the cover 35. In addition, in some embodiments the hinge assemblies 40 might be positioned in other locations, such as at the top and bottom of the cover 35 instead of (or in addition to) the left and right sides. The hinge assembly 40 components may be fabricated out of various materials such as metal (e.g., steel), etc., as will be appreciated by those skilled in the art.

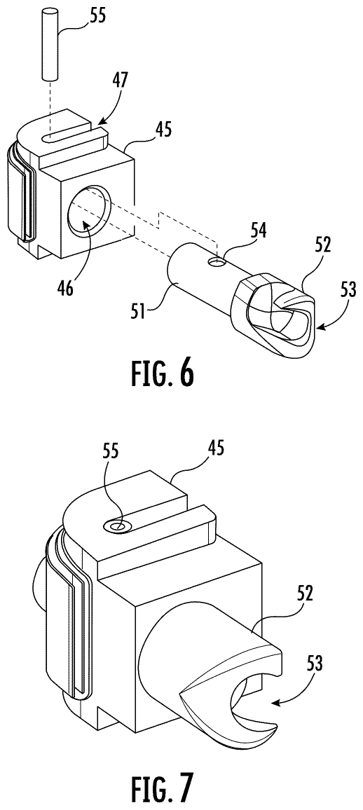

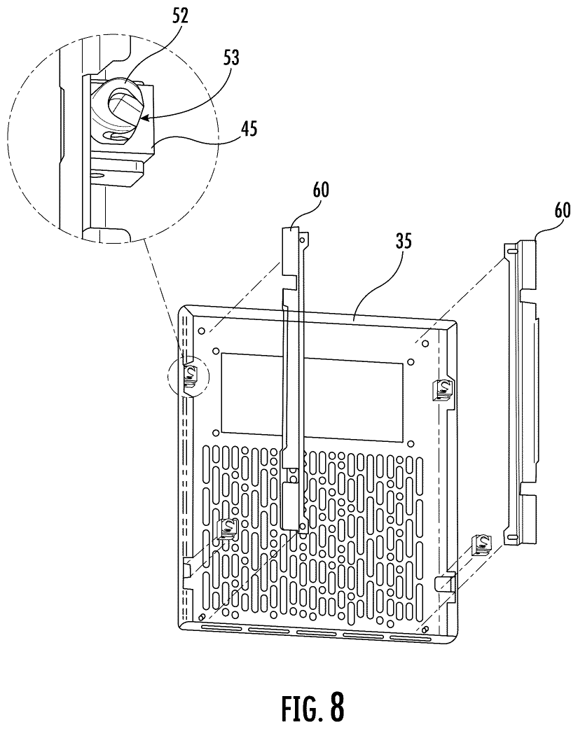

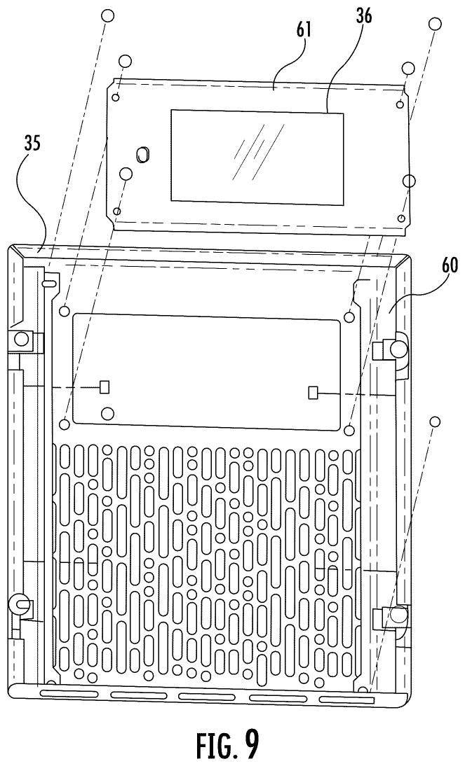

Turning to FIGS. 6-12, a method for making or assembling the enclosure 30 is now described. For each hinge assembly 40, a quick release bolt 50 is aligned with and inserted in the bolt receive channel 46 of a respective bolt capture block 45, with the locking pin hole 54 facing up or vertically so that a locking pin 55 may be inserted therein through the locking pin groove 47. The locking pin 55 not only serves to keep the quick release bolt 50 from pulling back out of the bolt receiving channel 46, but it may also provide stop limits for the angular rotation of the quick release bolt 50 between the locked and unlocked positions to help prevent over rotation. In the illustrated example, the quick release bolt 50 is rotatable over a range of ˜65°, though in different embodiments other ranges of angular travel may be used.

Once the quick release bolts 50 have been installed on all the bolt capture blocks 41, the bolt capture blocks may then be installed on the cover 35 using hinge brackets 60 and nuts/bolts, for example. In the illustrated example, the hinge brackets 60 are placed against the inside face of the front cover 35 with studs on the front cover through slots in the hinge brackets (FIG. 7). Moreover, there are two hinge assemblies 40 on the right side of the cover 35 and two on the left side of the cover in this example, but again different numbers of hinge assemblies 40 may be used in different embodiments depending on the type and/or size of the enclosure. Moreover, it should also be noted that the hinge assembly 40 design is scalable, such that different sizes of hinge assemblies may be used for different chassis 30 sizes and weights of the cover 35, for example. Furthermore, a display frame 61 including the window pane 36 is also mounted on the inside face of front cover 35. Again, the display frame 61 and windowpane 36 are optional to provide viewing through the opening into the chassis 30, but may be omitted in some configurations.

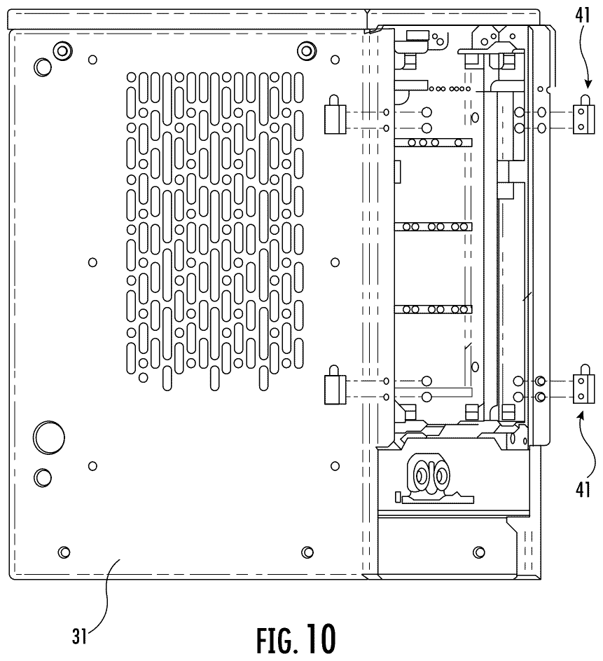

In a next step, the hinge pin blocks 41 are attached to the chassis 30 at the appropriate locations, e.g., with machine screws (FIG. 10). The cover 35 may then be installed onto chassis 30 (FIG. 11). With all four of the quick release bolts 50 rotated to the unlocked position (see FIG. 5B) using a hex (or other suitable) wrench, the slots 53 are aligned with the hinge pins 43 and the front cover 35 may slide into position. Using a hex wrench (e.g., a 5 mm hex wrench, although other sizes may be used as well) in the hex socket receptacle 56, all of the quick release bolts 50 are rotated ˜65° clockwise to the locked position (see FIG. 5A), as shown in the detailed region of FIG. 11. In some embodiments, index marks 62 may be provided which are vertically aligned when the quick release bolts are in the locked position (see detailed regions in FIG. 12). The chassis 30 includes rack mount fixtures 65 in the illustrated example for mounting equipment therein, although other suitable mounting fixtures may be used in different embodiments.

This process is reversed to remove the front cover 35 entirely for service or access by rotating all of the quick release bolts 50 counterclockwise to the unlocked position, at which point the cover may be lifted up and off of the hinge pins 43. Additionally, the cover 35 can be hinged open left handed or right handed by unlocking the quick release bolts 50 on one side or the other, as discussed above. FIG. 12 shows the hinged left side mode, in which the left side quick release bolts 50 are in the locked position, and FIG. 1 shows the hinged right mode in which the right-side bolts are in the locked position. With the left side quick release bolts 50 in the unlocked position, this allows the right side to swing open while the left side quick release bolts rotate on left side hinge pins, and vice-versa. Again, reversing the locked and unlocked bolts 50 allows the front cover 35 to swing open in the opposite direction. Stated alternatively, when a quick release bolt 50 is in the locked position, the bolt cannot pull free and separate from its respective hinge pin 43, but it is free to rotate about the hinge pin.

It should be noted that one or more of the steps of the assembly process described above may be performed in a different order in different embodiments, as will be appreciated by those skilled in the art. For example, the hinge pin blocks 41 could be installed at the beginning of the process, etc.

The above-described hinge assembly 40 provides a number of significant technical advantages. For example, it is relatively simple to install and operate, but it also does not require reconfiguration to switch handedness. The hinge assembly 40 is advantageously secure, suitable for industrial applications, and allows opening of the cover 35 in a number of different ways. The hinge assemblies 40 also serve as both hinges to swing open the cover 35 left or right, and latches to lock the cover in place (no swinging open), which advantageously reduces parts count and therefore cost/complexity with respect to typical enclosures. The hinge assemblies 40 accordingly provide for hinged covers 35 that overcome unknown constraints from installations of enclosures 20 in various different locations to provide enhanced installation options and user flexibility of operation.

Those skilled in the art will appreciate that certain of the example components described herein may be modified or even omitted in some embodiments. For example, the locking pin groove 47, locking pin hole 54, and locking pin 55 described above provide one implementation that may be used for limiting rotation, but in different implementations other components could be used such as screws, rings, clips, cams and/or other types of pins, etc., or even geometry that is integral to the quick release bolt 50 itself. Likewise, different configurations of the hinge brackets 60 could be used, or these may even be omitted in some configurations.

Furthermore, in the above-described embodiment, there is no need for a stop to prevent lifting the cover 35 off the hinge pins 43 when all four positions are locked because the front cover would be blocked from lifting off straight up along the axis of the hinge pins. However, in some embodiments the hinge pin block 41 may be extended to incorporate a stopping plate or surface that prevents the quick release bolt 50 from lifting off the hinge pin 43 when in either the locked or unlocked positions along the pin axis. For example, the surface that the mounting holes 44 are on may be extended past the hinge pin 43 and form a right angle over the rounded end of the hinge pin that would ensure that the quick release bolt 50 can only be removed by pulling away from the hinge pin as previously described above.

Many modifications and other embodiments will come to the mind of one skilled in the art having the benefit of the teachings presented in the foregoing descriptions and the associated drawings. Therefore, it is understood that the disclosure is not to be limited to the specific embodiments disclosed, and that modifications and embodiments are intended to be included within the scope of the appended claims.

1. An enclosure comprising:
a chassis having an opening therein;
a plurality of hinge pins coupled to the chassis adjacent the opening, with at least one first hinge pin positioned adjacent a first side of the opening and at least one second hinge pin positioned adjacent a second side of the opening opposite the first side;
a cover for the opening; and
a plurality of bolts rotatably carried by the cover, each bolt being aligned with a respective hinge pin when the cover is positioned over the opening in the chassis, and each bolt being rotatable between locked and unlocked positions with respect to its corresponding hinge pin such that
when the bolt corresponding to the at least one first hinge pin is in the locked position and the bolt corresponding to the at least one second hinge pin is in the unlocked position, the cover is rotatable about the at least one first hinge pin,
when the bolt corresponding to the at least one second hinge pin is in the locked position and the bolt corresponding to the at least one first hinge pin is in the unlocked position, the cover is rotatable about the at least one second hinge pin, and
when the bolts corresponding to the at least one first hinge pin and the at least one second hinge pin are in the unlocked position, the cover is removable from the chassis.

2. The enclosure of claim 1 wherein each bolt has a slot therein configured to engage the corresponding hinge pin when the bolt is rotated to the locked position, and to release the corresponding hinge pin when the bolt is rotated to the unlocked position.

3. The enclosure of claim 1 further comprising a plurality of bolt capture blocks removably attached to the cover and each for receiving a respective bolt therein.

4. The enclosure of claim 3 wherein each bolt has a locking pin hole, and wherein each bolt capture block has a locking pin groove therein for inserting a locking pin into the locking pin hole of the corresponding bolt.

5. The enclosure of claim 4 wherein the locking pin groove is configured to allow rotation of the locking pin between first and second and second stop positions.

6. The enclosure of claim 1 wherein each hinge pin comprises a rounded tip.

7. The enclosure of claim 1 wherein the at least one first hinge pin comprises at least two first hinge pins, and the at least one second hinge pin comprises at least two second hinge pins.

8. The enclosure of claim 1 further comprising a plurality of hinge pin bases each coupling a respective hinge pin to the chassis.

9. The enclosure of claim 1 further comprising at least one rack mount fixture carried within the chassis and configured to receive at least one electronic component.

10. A hinge system for an enclosure comprising a chassis having an opening therein and a cover for the opening, the hinge assembly comprising:
a plurality of hinge pins to be coupled to the chassis adjacent the opening, with at least one first hinge pin positioned adjacent a first side of the opening and at least one second hinge pin positioned adjacent a second side of the opening opposite the first side; and
a plurality of bolts to be rotatably carried by the cover, each bolt being aligned with a respective hinge pin when the cover is positioned over the opening in the chassis, and each bolt being rotatable between locked and unlocked positions with respect to its corresponding hinge pin such that
when the bolt corresponding to the at least one first hinge pin is in the locked position and the bolt corresponding to the at least one second hinge pin is in the unlocked position, the cover is rotatable about the at least one first hinge pin,
when the bolt corresponding to the at least one second hinge pin is in the locked position and the bolt corresponding to the at least one first hinge pin is in the unlocked position, the cover is rotatable about the at least one second hinge pin, and
when the bolts corresponding to the at least one first hinge pin and the at least one second hinge pin are in the unlocked position, the cover is removable from the chassis.

11. The hinge system of claim 10 wherein each bolt has a slot therein configured to engage the corresponding hinge pin when the bolt is rotated to the locked position, and to release the corresponding hinge pin when the bolt is rotated to the unlocked position.

12. The hinge system of claim 10 further comprising a plurality of bolt capture blocks removably attached to the cover and each for receiving a respective bolt therein.

13. The hinge system of claim 12 wherein each bolt has a locking pin hole, and wherein each bolt capture block has a locking pin groove therein for inserting a locking pin into the locking pin hole of the corresponding bolt.

14. The hinge system of claim 10 wherein each hinge pin comprises a rounded tip.

15. The hinge system of claim 10 wherein the at least one first hinge pin comprises at least two first hinge pins, and the at least one second hinge pin comprises at least two second hinge pins.

16. The hinge system of claim 10 further comprising a plurality of hinge pin bases each coupling a respective hinge pin to the chassis.

17. A method for making an enclosure comprising:
coupling a plurality of hinge pins to a chassis adjacent an opening thereof, with at least one first hinge pin positioned adjacent a first side of the opening and at least one second hinge pin positioned adjacent a second side of the opening opposite the first side; and
attaching a plurality of bolts to a cover for the opening of the chassis, each bolt being aligned with a respective hinge pin when the cover is positioned over the opening in the chassis, and each bolt being rotatable between locked and unlocked positions with respect to its corresponding hinge pin such that
when the bolt corresponding to the at least one first hinge pin is in the locked position and the bolt corresponding to the at least one second hinge pin is in the unlocked position, the cover is rotatable about the at least one first hinge pin,
when the bolt corresponding to the at least one second hinge pin is in the locked position and the bolt corresponding to the at least one first hinge pin is in the unlocked position, the cover is rotatable about the at least one second hinge pin, and
when the bolts corresponding to the at least one first hinge pin and the at least one second hinge pin are in the unlocked position, the cover is removable from the chassis.

18. The method of claim 17 wherein each bolt has a slot therein configured to engage the corresponding hinge pin when the bolt is rotated to the locked position, and to release the corresponding hinge pin when the bolt is rotated to the unlocked position.

19. The method of claim 17 further comprising removably attaching a plurality of bolt capture blocks to the cover and each for receiving a respective bolt therein.

20. The method of claim 19 wherein each bolt has a locking pin hole, and wherein each bolt capture block has a locking pin groove therein; and further comprising inserting a locking pin into the locking pin hole of the corresponding bolt.

21. The method of claim 17 wherein each hinge pin comprises a rounded tip.

22. The method of claim 17 wherein the at least one first hinge pin comprises at least two first hinge pins, and the at least one second hinge pin comprises at least two second hinge pins.
